(19) United States
(12) Patent Application Publication
(10) Pub. No.: US 2023/0325689 A1
(43) Pub. Date: Oct. 12, 2023

(54) ADAPTIVE DEEP LEARNING-BASED INTELLIGENT PREDICTION METHOD, APPARATUS, AND DEVICE FOR COMPLEX INDUSTRIAL SYSTEM, AND STORAGE MEDIUM

(71) Applicant: NORTHEASTERN UNIVERSITY, Shenyang (CN)

(72) Inventors: Tianyou Chai, Shenyang (CN); Suting Gao, Shenyang (CN)

(21) Appl. No.: 18/208,881

(22) Filed: Jun. 12, 2023

Related U.S. Application Data
(63) Continuation of application No. PCT/CN2021/136373, filed on Dec. 8, 2021.

(30) Foreign Application Priority Data
Dec. 10, 2020 (CN) 202011435304.2

(51) Int. Cl. G06N 5/022; G06N 3/08

(52) U.S. Cl. CPC G06N 5/022; G06N 3/08

(57) ABSTRACT

Disclosed are an adaptive deep learning-based intelligent prediction method, apparatus, and device for a complex industrial system, and a storage medium. The method includes establishing a dynamic model for a complex industrial system; establishing an offline deep learning prediction model using the dynamic model; establishing an online deep learning prediction model using the offline deep learning prediction model; establishing a deep learning correction model based on a structure that is the same as a structure of the online deep learning prediction model; and correcting the online deep learning prediction model using the deep learning correction model; where the online deep learning prediction model predicts a parameter of the complex industrial system in real time. The offline deep learning prediction model, the online deep learning prediction model, the deep learning correction model, and a self-correction mechanism are established to achieve accurate real-time prediction of the complex industrial system.

### CROSS REFERENCE TO RELATED APPLICATIONS

The present application is a Continuation Application of PCT Application No. PCT/CN2021/136373 filed on Dec. 8, 2021, which claims the benefit of Chinese Patent Application No. 202011435304.2 filed on Dec. 10, 2020. All the above are hereby incorporated by reference in their entirety.

### TECHNICAL FIELD

The present disclosure belongs to the technical field of artificial intelligence in industry, and relates to an adaptive deep learning-based intelligent prediction method, apparatus, and device for a complex industrial system, and a storage medium.

### BACKGROUND

In order to achieve closed-loop optimization decision-making in a production process, it is necessary to online predict production indicators representing quality, efficiency, and energy consumption of a product, and key process parameters. Due to a short time cycle of closed-loop optimization decision-making in an industrial process, a prediction model for the production indicators and the key process parameters is required to provide a predictive value in the decision-making time cycle. This requires that a training dataset of a deep learning prediction model should not be too large, and a training algorithm should not take too long. In addition, due to the complexity of a manufacturing process, the production indicators, the key process parameters, and the input and output variables of a related production process are complex dynamic systems. The dynamic system often has strong nonlinearity and strong coupling of a plurality of variables. A model structure and orders of the input and output variables are unknown or even changing, production boundary conditions such as production raw materials change, and a material flow, an information flow, and an energy flow in the production process act upon each other. This causes an unknown change to a characteristic of the dynamic system with production time, and as a result, the input and output data of the system is in changing, open, and uncertain information space. This makes it impossible to apply an existing deep learning technology with complete information space to the above complex industrial dynamic system to establish a prediction model for the complex industrial dynamic system.

### SUMMARY

The present disclosure is intended to resolve at least one of technical problems in the related art. Technical solutions of the present disclosure are as follows:

An adaptive deep learning-based intelligent prediction method for a complex industrial system includes following steps:

establishing a dynamic model for a complex industrial system;

establishing an offline deep learning prediction model by using the dynamic model;

establishing an online deep learning prediction model by using the offline deep learning prediction model;

establishing a deep learning correction model based on a structure that is the same as a structure of the online deep learning prediction model; and

correcting the online deep learning prediction model by using the deep learning correction model; where

the online deep learning prediction model is configured to predict a parameter of the complex industrial system in real time.

Further, preferably, the establishing a dynamic model for a complex industrial system includes: determining an input variable and an output variable of the dynamic model, where the output variable is a predicted variable; the establishing an offline deep learning prediction model by using the dynamic model includes: establishing the offline deep learning prediction model by using a long-short term memory (LSTM) network, using the input variable of the dynamic model as an input of the LSTM network, using output data of the dynamic model as labels, and determining a neuron quantity, a cell node quantity, and a network layer quantity of the LSTM network, and weight and bias parameters of each layer by using an offline training algorithm based on an error between the labels and an output of the offline deep learning prediction model; the establishing an online deep learning prediction model by using the offline deep learning prediction model includes: establishing the online deep learning prediction model by using an LSTM network, where an input of a single neuron, a neuron quantity, a cell node quantity, and a network layer quantity of the online deep learning prediction model are all the same as those of the offline deep learning prediction model; using weight and bias parameters of each layer of the offline deep learning prediction model as initial values of weight and bias parameters of the corresponding layer of the online deep learning prediction model; and correcting weight and bias parameters of a last layer of the online deep learning prediction model online by using the online training algorithm based on an error between the labels and an output of the online deep learning prediction model; the establishing a deep learning correction model based on a structure that is the same as a structure of the online deep learning prediction model includes: establishing the deep learning correction model by using an LSTM network, where an input of a single neuron, a neuron quantity, a cell node quantity, and a network layer quantity of the deep learning correction model are all the same as those of the online deep learning prediction model; and correcting weight and bias parameters of each layer of the deep learning correction model in real time by using a training algorithm based on an error between the labels and an output of the deep learning correction model; and the correcting the online deep learning prediction model by using the deep learning correction model includes: when a preset condition is met, replacing weight and bias parameters of each layer of the online deep learning prediction model with weight and bias parameters of the corresponding layer of the deep learning correction model; where historical data input into the deep learning correction model is more than historical data input into the online deep learning prediction model.

Further, preferably, the correcting weight and bias parameters of a last layer of the online deep learning prediction model online is specifically correcting some weight parameters and some bias parameters of the last layer of the online deep learning prediction model online.

Further, preferably, the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

An adaptive deep learning-based intelligent prediction apparatus for a complex industrial system includes:

a dynamic model establishment module configured to establish a dynamic model for a complex industrial system;

an offline deep learning prediction model establishment module configured to establish an offline deep learning prediction model by using the dynamic model;

an online deep learning prediction model establishment module configured to establish an online deep learning prediction model by using the offline deep learning prediction model;

a deep learning correction model establishment module configured to establish a deep learning correction model based on a structure that is the same as a structure of the online deep learning prediction model; and

a self-correction module configured to correct the online deep learning prediction model by using the deep learning correction model; where

the online deep learning prediction model is configured to predict a parameter of the complex industrial system in real time.

Further, preferably, the dynamic model establishment module determines an input variable and an output variable of the dynamic model, where the output variable is a predicted variable; the offline deep learning prediction model establishment module establishes the offline deep learning prediction model by using an LSTM network, uses the input variable of the dynamic model as an input of the LSTM network, uses output data of the dynamic model as labels, and determines a neuron quantity, a cell node quantity, and a network layer quantity of the LSTM network, and weight and bias parameters of each layer by using an offline training algorithm based on an error between the labels and an output of the offline deep learning prediction model; the online deep learning prediction model establishment module establishes the online deep learning prediction model by using an LSTM network, where an input of a single neuron, a neuron quantity, a cell node quantity, and a network layer quantity of the online deep learning prediction model are all the same as those of the offline deep learning prediction model; uses weight and bias parameters of each layer of the offline deep learning prediction model as initial values of weight and bias parameters of the corresponding layer of the online deep learning prediction model; and corrects weight and bias parameters of a last layer of the online deep learning prediction model online by using the online training algorithm based on an error between the labels and an output of the online deep learning prediction model; the deep learning correction model establishment module establishes the deep learning correction model by using an LSTM network, where an input of a single neuron, a neuron quantity, a cell node quantity, and a network layer quantity of the deep learning correction model are all the same as those of the online deep learning prediction model; and corrects weight and bias parameters of each layer of the deep learning correction model in real time by using a training algorithm based on an error between the labels and an output of the deep learning correction model; and when a preset condition is met, the self-correction module replaces weight and bias parameters of each layer of the online deep learning prediction model with weight and bias parameters of the corresponding layer of the deep learning correction model; where more historical data is input into the deep learning correction model compared with the online deep learning prediction model.

Further, preferably, the correcting weight and bias parameters of a last layer of the online deep learning prediction model online is specifically correcting some weight parameters and some bias parameters of the last layer of the online deep learning prediction model online.

Further, preferably, the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

An adaptive deep learning-based intelligent prediction device for a complex industrial system to implement the above intelligent prediction method, where the device includes an end subdevice, an edge subdevice, and a cloud subdevice;

the end subdevice is configured to collect input data and output data of the complex industrial system;

the edge subdevice is configured to predict a parameter of the complex industrial system in real time by using an online deep learning prediction model; and

the cloud subdevice is configured to train a deep learning correction model and correct the online deep learning prediction model by using the deep learning correction model.

A computer-readable storage medium storing a computer program is provided, where the computer program is executed by a processor to perform the above intelligent prediction method for a complex industrial system.

In order to resolve problems of low prediction accuracy and poor real-time prediction performance of the complex industrial system, the present disclosure establishes the offline deep learning prediction model, the online deep learning prediction model, the deep learning correction model, and a self-correction mechanism to achieve accurate real-time prediction of the complex industrial system.

### BRIEF DESCRIPTION OF THE DRAWINGS

FIG. 1 is a flowchart of implementing an intelligent prediction method for a complex industrial system according to an embodiment of the present disclosure;

FIG. 2 is a flowchart of implementing an intelligent prediction method for a caustic concentration detection error according to an embodiment of the present disclosure;

FIG. 3 shows prediction errors of an online deep learning prediction model when a time sequence window of input data takes different lengths;

FIG. 4 is a schematic structural diagram of an intelligent prediction apparatus for a complex industrial system according to an embodiment of the present disclosure; and

FIG. 5 is a schematic structural diagram of an intelligent prediction device for a complex industrial system according to an embodiment of the present disclosure.

### DETAILED DESCRIPTION

The technical solutions in the embodiments of the present disclosure are clearly and completely described below with reference to the drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts should fall within the protection scope of the present disclosure.

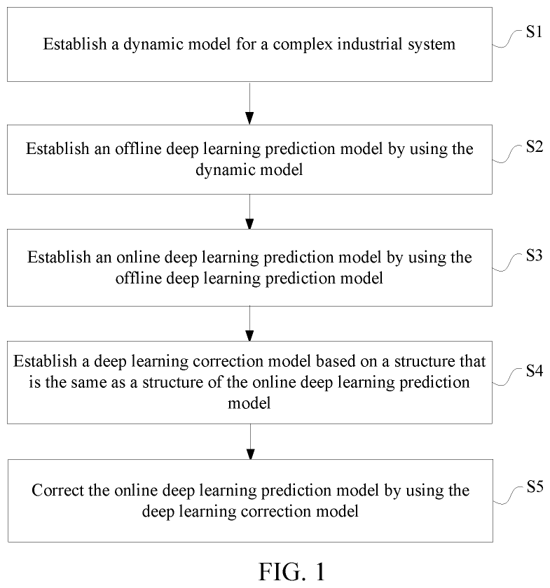

FIG. 1 is a flowchart of implementing an intelligent prediction method for a complex industrial system according to an embodiment of the present disclosure. The method includes following steps:

S1: Establish a dynamic model for a complex industrial system.

Specifically, through mechanism analysis of an industrial process, a to-be-predicted production indicator or key process parameter is used as an output variable of the dynamic model for the industrial system, and an input and an output of the industrial process that affect the output variable are used as input variables of the dynamic model, historical output data and historical prediction error data of the dynamic model are used as input variables of the dynamic model, and an unknown constant n is used to represent an order of an unknown change in the input and output variables of the dynamic model. The dynamic model for the industrial system is expressed as follows:

s(k)=f(s(k−1), . . . ,s(k−n),yᵢ(k), . . . ,yᵢ(k−n+1),uᵢ(k), . . . ,uᵢ(k−n+1),Δs(k−1), . . . ,Δs(k−n)) (1)

In the above formula, f represents a nonlinear function of the unknown change; s(k) represents an output of the dynamic model at a k^{th} time point; yᵢ(k) represents an i^{th} output of the industrial process at the k^{th} time point, uᵢ(k) represents an i^{th} input of the industrial process at the k^{th} time point, and i=1, . . . , m; and Δs(k−1)=s(k−1)−ŝ(k−1) represents a prediction error at a k−1^{th} time point, in other words, a difference between an output s(k−1) of the dynamic model and an output ŝ(k−1) of a prediction model at the k−1^{th} time point.

S2: Establish an offline deep learning prediction model by using the dynamic model.

Specifically, the offline deep learning prediction model is established by using an LSTM network, the input variable of the dynamic model is used as an input of the LSTM network, output data of the dynamic model is used as labels, and a neuron quantity, a cell node quantity, and a network layer quantity of the LSTM network, and weight and bias parameters of each layer are determined by using an offline training algorithm based on an error between the labels and an output of the offline deep learning prediction model.

The step S2 includes substeps S21 and S22.

Step S21: Establish the offline deep learning prediction model by an LSTM network structure, set an initial network layer quantity of the LSTM network to 1, and determine the neuron quantity and the cell node quantity of the LSTM network by using a training algorithm based on a difference between the labels and the output of the offline deep learning prediction model.

Specifically, the input variable in the formula (1) is selected as an input xⱼ(k+j−n) (j=1, . . . , n) of a j^{th} single neuron, with an order n being the neuron quantity, in other words,

xⱼ(k+j−n)=[s(k+j−n−1),yᵢ(k+j−n),uᵢ(k+j−n),Δs(k+j−n−1))]^{T} (2)

In the above formula, j=1, . . . , n; i=1, . . . , m.

The output data s(k) of the dynamic model (which is represented by the formula (1)) for the industrial system is used as the labels, the input and output data of the formula (1) is used to form a big data sample. The offline training algorithm is used to minimize the difference between the labels and the output of the offline deep learning prediction model, thereby determine the neuron quantity n and the cell node quantity h̅ of the LSTM network.

Step S22: Set the neuron quantity and the cell node quantity of the LSTM network to fixed values, and change the network layer quantity of the LSTM network, specifically, select the network layer quantity of the LSTM network based on differences between the labels and the output of the offline deep learning prediction model that correspond to different network layer quantities.

Specifically, the neuron quantity n and the cell node quantity h̅ of the LSTM network are set to the fixed values, and the error between the output of the offline deep learning prediction model and the labels is minimized by increasing the network layer quantity of the LSTM network, to determine the network layer quantity of the LSTM network, and the weight and bias parameters of each layer.

S3: Establish an online deep learning prediction model by using the offline deep learning prediction model.

Specifically, the online deep learning prediction model is established by using an LSTM network, where an input of a single neuron, a neuron quantity, a cell node quantity, and a network layer quantity of the online deep learning prediction model are all the same as those of the offline deep learning prediction model; weight and bias parameters of each layer of the offline deep learning prediction model are used as initial values of weight and bias parameters of the corresponding layer of the online deep learning prediction model; and weight and bias parameters of a last layer of the online deep learning prediction model are corrected online by using a time sequence N with a fixed data amount, to ensure that the online deep learning prediction model completes a prediction algorithm within a determined optimization decision-making time period. The training algorithm is used to determine the N by minimizing the prediction error. It is obtained, by using a dataset with a time sequence length of the N and a recursive algorithm, that a time sequence of input data of the online deep learning prediction model at the k^{th} time point is (k−N+1), . . . , k and a time sequence of the input data of the online deep learning prediction model at a (k+1)^{th} time point is (k−N+2), . . . , (k+1). The online deep learning prediction model is configured to predict a parameter of the complex industrial system in real time.

S4: Establish a deep learning correction model based on a structure that is the same as a structure of the online deep learning prediction model.

Specifically, the deep learning correction model is established by using an LSTM network. An input of a single neuron, a neuron quantity, a cell node quantity, and a network layer quantity of the deep learning correction model are all the same as those of the online deep learning prediction model. Input data of the model (which is represented by the formula (1)) at a current time points and all previous time points is used as input data of the deep learning correction model, all weight and bias parameters of each layer of the deep learning correction model are trained to obtain a predictive value \tilde{s}(k) and a prediction error Δ\tilde{s}(k)=s(k)−\tilde{s}(k) of the deep learning correction model.

S5: Correct the online deep learning prediction model by using the deep learning correction model.

Specifically, the deep learning correction model is used to adaptively correct the online deep learning prediction model, and an upper limit of a prediction error range is set to δ. When a prediction error of the online deep learning prediction model meets |Δs(k)|≥δ, and the prediction error of the deep learning correction model meets |Δ\tilde{s}(k)|<δ, weight and bias parameters of each layer of the deep learning correction model are used to replace weight and bias parameters of the corresponding layer of the online deep learning prediction model to ensure that the prediction error of the online deep learning prediction model is within a specified prediction error range, namely |Δ\tilde{s}(k)|<δ.

Further, in an embodiment, the intelligent prediction method for a complex industrial system can be used to predict a caustic concentration detection error of an alumina production system.

Alumina has excellent properties such as high hardness and high melting point, and is commonly used to smelt metallic alumina and manufacture refractory materials. The alumina is a strategic resource that plays a supporting role in the military industry, aerospace, and national economy. At present, a main method for producing the alumina is the Bayer process. According to the Bayer process, crushed bauxite with lime and a caustic solution added according to a required ratio is usually ground. Then, bauxite is dissolved from the caustic solution at a certain temperature and pressure to produce a sodium aluminate solution. An aluminum hydroxide crystal is decomposed and precipitated by purifying the sodium aluminate solution, cooling a purified sodium aluminate solution, adding a seed crystal to the sodium aluminate solution, and stirring the sodium aluminate solution. A precipitated aluminum hydroxide is separated, washed, and roasted to obtain the alumina. A mother liquor (mainly composed of caustic) obtained by separating the aluminum hydroxide undergoes an evaporation process to dissolve new bauxite for a next cycle.

A caustic concentration of an alumina solution is a key process indicator in an evaporation process of the alumina, which is related to final product quality of the alumina. Daily caustic concentration detection is to obtain an accurate caustic concentration value through manual sampling based on a fixed cycle and subsequent testing. However, due to a long sampling interval and long testing time, the caustic concentration cannot be detected in a timely manner, which makes it impossible to achieve operation optimization and control of the evaporation process.

In order to achieve the operation optimization and control of the evaporation process, some alumina enterprises have introduced an online caustic concentration measurement apparatus at an expensive price. In actual production, a grade change of the bauxite and an operation change of a production process of the bauxite result in a significant difference between a caustic concentration measured by the measurement apparatus and a laboratory result. As a result, the caustic concentration measured by the measurement apparatus cannot be used. Due to unknown strong nonlinearity of a dynamic property of the error, an unknown model order, frequent fluctuations in production boundary conditions such as raw materials, and interactions between various process flows and materials, a characteristic of an error dynamic system undergoes an unknown change with production time. As a result, input and output data of the system is in changing, open, and uncertain information space. This makes it impossible to apply an existing deep learning technology with complete information space to a dynamic system for predicting a caustic concentration error in the evaporation process of the alumina. In addition, due to a short time cycle of operation optimization decision-making in an industrial process of producing the alumina, a prediction model for production indicators and key process parameters is required to provide a predictive value in the decision-making time cycle. This requires that a training dataset of the deep learning prediction model should not be too large, and the training algorithm should not take too long.

In order to resolve problems of low prediction accuracy and poor real-time prediction performance of the alumina production system, the offline deep learning prediction model, the online deep learning prediction model, the deep learning correction model, and a self-correction mechanism have been established to achieve accurate real-time prediction of the alumina production system.

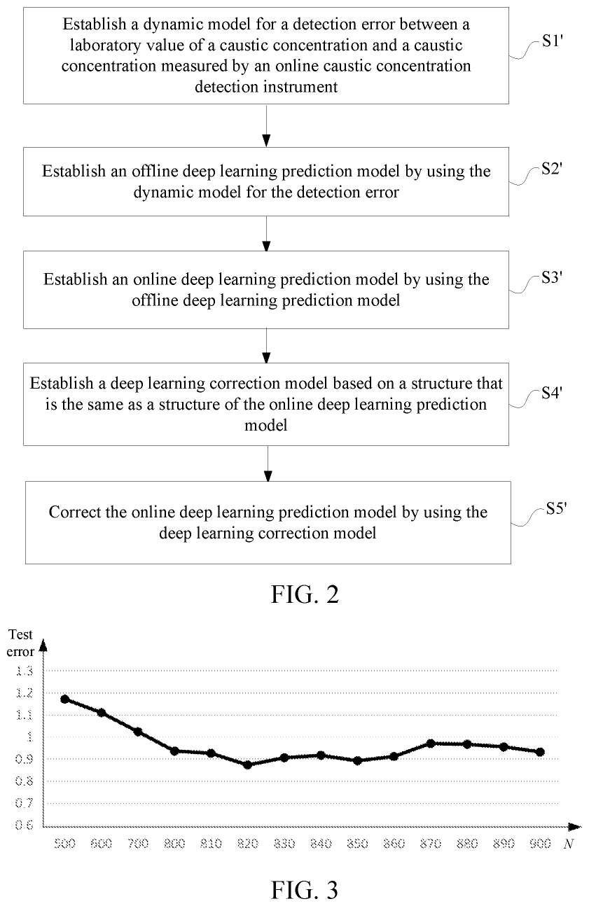

FIG. 2 is a flowchart of implementing an intelligent prediction method for a caustic concentration detection error according to an embodiment of the present disclosure. The method includes following steps:

S1′: Establish a dynamic model for a detection error between a laboratory value of a caustic concentration and a caustic concentration measured by an online caustic concentration detection instrument.

Specifically, since the online caustic concentration detection instrument takes a refractive index and a temperature of an alumina solution as inputs, and generates a measured concentration value by using the model. Therefore, the refractive index and the temperature of the alumina solution are used as inputs of the dynamic model for the detection error, and a historical difference between the laboratory value of the caustic concentration and the caustic concentration measured by the caustic concentration detection instrument is used as an input of the dynamic model for the detection error. An unknown constant n is used to represent an unknown order of input and output variables of the dynamic model, and the dynamic model for the detection error of the caustic concentration is established as follows:

Δr(k)=\hat{f}(y₁(k), . . . ,y₁(k−n+1),y₂(k), . . . ,y₂(k−n+1),Δr(k−1), . . . ,Δr(k−n)) (3)

In the above model, \hat{f} represents a nonlinear function of an unknown change; y₁(k) represents a refractive index of the alumina solution at a k^{th} time point; y₂(k) represents a temperature of the alumina solution at the k^{th} time point; and Δr(k)=r(k)−r̅(k), which is a difference between a laboratory value r(k) of the caustic concentration and a caustic concentration r̅(k) measured by the caustic concentration detection instrument at the k^{th} time point.

S2′: Establish an offline deep learning prediction model by using the dynamic model for the detection error.

Specifically, the offline deep learning prediction model is established by using an LSTM network, the input variable of the dynamic model for the detection error is used as an input of the LSTM network, output data of the dynamic model for the detection error is used as labels, and a neuron quantity, a cell node quantity, and a network layer quantity of the LSTM network, and weight and bias parameters of each layer are determined by using an offline training algorithm based on an error between the labels and an output of the offline deep learning prediction model.

The step ST includes substeps S21′ and S22′.

Step S21′: Establish the offline deep learning prediction model by an LSTM network structure, set an initial network layer quantity of the LSTM network to 1, and determine the neuron quantity and the cell node quantity of the LSTM network by using a training algorithm based on the difference between the labels and the output of the offline deep learning prediction model.

Specifically, a j^{th} input variable in the formula (3) is selected as an input xⱼ(k+j−n) (j=1, . . . , n) of a P single neuron, namely:

xⱼ(k+j−n)=[y₁(k+j−n),y₂(k+j−n),Δr(k+j−n−1)]^{T} (4)

In the above formula, j=1, . . . , n, and n represents the neuron quantity.

The neuron quantity n and the cell node quantity h̅ of the LSTM network are determined by using the following training algorithm:

An LSTM network neural network with a layer quantity being 1 is selected, and an error between labels Δr(k) at the k^{th} time point and an output Δ\hat{r}₀(k) of the offline deep learning prediction model at the k^{th} time point is minimized by using a big data sample constituted by the input and output variables shown in the formula (3), taking an error Δr(k) between the laboratory value of the caustic concentration and the caustic concentration measured by the measurement instrument as the labels, and using the training algorithm, to determine the n and the h̅.

An objective function of the training algorithm is as follows:

$${ℒ}_{MAE} ( Δ {\hat{r}}_{0} , Δ r ) = \frac{{\sum }_{k = 1}^{M} {‖ Δ r ( k ) - Δ {\hat{r}}_{0} ( k ) ‖}_{1}}{M} \qquad ( 5 )$$

In the above objective function, M represents an amount of training data.

The labels Δr(k) is obtained according to a following formula:

Δr(k)=r(k)−r̅(k) (6)

A predictive value Δ\hat{r}₀(k) of the offline deep learning prediction model is a weighted expression of an output h(k) of an n^{th} neuron:

Δ\hat{r}₀(k)=W_{d}×h(k)+b_{d} (7)

In the above expression, h(k) represents an h̅×1 vector, W_{d} represents a weight parameter, W_{d} represents a 1×h̅ vector, and b_{d} represents a bias parameter.

h(k)=oₖ*tanh(C(k)) (8)

In the above formula, oₖ represents an input of an output gate, and oₖ represents an h̅×1 vector.

oₖ=σ(Wₒ·[h(k−1),xⱼ(k)]^{T}+bₒ) (9)

In the above formula, h(k−1) represents an output of an (n−1)^{th} neuron, [h(k−1), xⱼ(k)]^{T} represents an (h̅+3)×1 vector, Wₒ and bₒ represent a connection weight and bias of a first layer of the neural network, respectively, Wₒ represents a h̅×h̅(h̅+3) matrix, and bₒ represents an h̅×1 vector. σ represents a sigmoid function, σ( [symbol] )=( [symbol] )⁻¹, and [symbol] represents an element of a vector [Wₒ·[h(k−1),xⱼ(k)]^{T}+bₒ].

C(k) represents a long-term memory state, C(k) represents an it h̅×1 vector, tanh(·) represents a hyperbola tangent function,

$$tanh ( {c}_{i} ( k ) ) = \frac{sinh ( {c}_{i} ( k ) )}{cosh ( {c}_{i} ( k ) )} ,$$

cᵢ(k) represents an i^{th} element of the vector C(k), and i∈[1, L h̅].

C(k)=fₖ*C(k−1)+iₖ* [symbol] (10)

In the above formula, fₖ, iₖ, and [symbol] each represent an h̅×1 vector, respectively, which are calculated according to following formulas:

fₖ=σ(W_{f}·[h(k−1),xⱼ(k)]^{T}+b_{f})

iₖ=σ(Wᵢ·[h(k−1),xⱼ(k)]^{T}+bᵢ)

[symbol]

=tanh(W_{C}·[h(k−1),xₕ(k)]^{T}+b_{C}) (11)

In the above formulas, W_{f}, Wᵢ, and W_{C} are connection weights of an LSTM network cell, which are all the h̅×(h̅+3) matrix; and b_{f}, bᵢ, and b_{C} represent biases of the LSTM network cell, which are all the h̅×1 vector.

It is specified that n=1,2L 22 and h̅=1, 2L 205. The formulas (5) to (11) are used to minimize the formula (5) by using a gradient descent algorithm. During an experiment, when the neuron quantity n is 20 and the cell node quantity h̅ of the LSTM network is 180, there is a minimum test error. Therefore, it is determined that the neuron quantity n is 20 and the cell node quantity h̅ of the LSTM network is 180.

Step S22′: Constantly set the neuron quantity n of the offline deep learning prediction model to 20 and the cell node quantity h̅ to 180, and minimize the error between the output Δ\hat{r}₀(k) of the offline deep learning prediction model and the labels Δr(k) by increasing the network layer quantity, to determine the layer quantity L.

The objective function of the training algorithm is shown in the formula (5), and an expression of the labels is shown in the formula (6). The predictive value Δ\hat{r}₀(k) of the offline deep learning prediction model is a weighted expression of an output h^{L}(k) of a 20^{th} neuron of an L^{th} layer of the LSTM network:

Δ\hat{r}₀(k)=W_{d}^{L}×h^{L}(k)+b_{d}^{L} (12)

In the above expression, h^{L}(k) represents a 180×1 vector, W_{d}^{L} represents a weight parameter, W_{d}^{L} represents a 1×180 vector, and b_{d}^{L} represents a bias parameter.

h^{L}(k)=oₖ^{L}*tanh(C^{L}(k)) (13)

In the above formula, oₖ^{L} represents an input of the output gate, and oₖ^{L} represents a 180×1 vector.

oₖ^{L}=σ(Wₒ^{L}·[h^{L}(k−1),h^{L-1}(k)]^{T}+bₒ^{L}) (14)

In the above formula, h^{L}(k −1) represents an output of a 19^{th} neuron of an L^{th} layer of the LSTM network neural network, and h^{L-1}(k) represents an output of a 20^{th} neuron of an (L−1)^{th} layer of the LSTM network neural network, and an input of the 20^{th} neuron of the L^{th} layer of the LSTM network.

C^{L}(k) represents a long-term memory state, and C^{L}(k) represents a 180 ×1 vector.

C^{L}(k)=fₖ^{L}*C^{L}(k−1)+iₖ^{L}* [symbol] (15)

In the above formula, fₖ^{L}, iₖ^{L}, and [symbol] each represent a 180×1 vector, respectively, which are calculated according to following formulas:

fₖ^{L}=σ(W_{f}^{L}·[h^{L}(k−1),h^{L-1}(k)]^{T}+b_{f}^{L})

iₖ^{L}=σ(Wᵢ^{L}·[h^{L}(k−1),h^{L-1}(k)]^{T}+bᵢ^{L})

[symbol]

=tanh(W_{C}^{L}·[h^{L}(k−1),h^{L-1}(k)]^{T}+b_{C}^{L}) (16)

In the above formulas, connection weights W_{f}^{L}, Wᵢ^{L}, W_{C}^{L}, and Wₒ^{L} of an LSTM network cell each are a 180×360 matrix, and biases b_{f}^{L}, bᵢ^{L}, b_{C}^{L}, and bₒ^{L} of the LSTM network cell are a 180×1 vector, respectively.

It is specified that L=1,2,3,4, and the formulas (5), (6), and (12) to (16) are used to minimize the formula (5) by using the gradient descent algorithm. An experimental result is shown in Table 1. When the layer quantity L of the LSTM network neural network is 2, highest prediction accuracy is achieved and training time is short. Therefore, it is determined that there are two neural network layers, and connection weight and bias parameters of each layer of the offline deep learning prediction model are also determined.

TABLE 1
Test error and layer quantity of an LSTM
network cell in the neural network

Layer quantity of the LSTM network cell

| | 1 | 2 | 3 | 4 |
|---|---|---|---|---|
| RMSE | 1.942 | 1.81 | 1.841 | 1.955 |
| MAE | 0.641 | 0.5573 | 0.587 | 0.770 |
| MAPE | 0.275 | 0.239 | 0.251 | 0.329 |
| Iteration cycle | <0.5 s | 1 s | 43 s | 111 s |

S3′: Establish an online deep learning prediction model by using the offline deep learning prediction model.

Specifically, the online deep learning prediction model is established by using an LSTM network. An input of a single neuron, a neuron quantity, a cell node quantity, and a network layer quantity of the online deep learning prediction model are all the same as those of the offline deep learning prediction model. Weight and bias parameters of each layer of the offline deep learning prediction model are used as initial values of weight and bias parameters of the corresponding layer of the online deep learning prediction model. A connection weight W_{d}² and a bias b_{d}² of a second layer of the online deep learning prediction model are corrected online.

The online deep learning prediction model is as follows:

Δ\hat{r}₁=W_{d}²(k)×h²(k)+b_{d}²(k) (17)

In the above online deep learning prediction model, W_{d}²(k) represents a correction value of W_{d}² at the k^{th} time point, W_{d}²(k)∈ [symbol] , b_{d}²(k) represents a correction value of b_{d}² at the k^{th} time point, and h²(k) represents an output of a last neuron in a second layer of the LSTM network cell. To ensure that a prediction algorithm is completed online within a specified prediction cycle, a length N of a time sequence window of input data of the online deep learning prediction model is determined through traversal.

An objective function is as follows:

$${ℒ}_{MAE}^{N} ( Δ {\hat{r}}_{1} , Δ r ) = \frac{{\sum }_{k - N + 1}^{k} {‖ Δ r ( k ) - Δ {\hat{r}}_{1} ( k ) ‖}_{1}}{N} \qquad ( 18 )$$

Correction algorithms for the W_{d}² and the b_{d}² are as follows:

$${W}_{d}^{2} := {W}_{d}^{2} + η \frac{\partial ( {ℒ}_{MAE}^{N} ( Δ {\hat{r}}_{1} , Δ r ) )}{\partial {W}_{d}^{2}} \qquad ( 19 )$$

$${b}_{d}^{2} := {b}_{d}^{2} + η \frac{\partial ( {ℒ}_{MAE}^{N} ( Δ {\hat{r}}_{1} , Δ r ) )}{\partial ( {b}_{d}^{2} )} \qquad ( 20 )$$

It is specified that N=500,L,900. The W_{d}² and the b_{d}² are corrected by using the above algorithms. An experimental result of the prediction error is calculated by using the formulas (17) and (18), as shown in FIG. 3. When the N is less than 820, an accuracy requirement of the prediction model cannot be met. When the N is greater than 820, a redundancy is generated, and network computation is increased. When the N is 820, a minimum prediction error is achieved. Therefore, it is determined that a time length of an input data sequence of the online deep learning prediction model is N=820.

Correspondingly, an online deep learning prediction model for a caustic concentration detection error at a (k+1)^{th} time point is as follows:

Δ\hat{r}₁(k+1)=W_{d}²(k+1)×h²(k+1)+b_{d}²(k+1) (21)

The online deep learning prediction model at the (k+1)^{th} time point uses input data of a time sequence (k−818), (k−817), . . . , (k+1) with N=820 at the (k+1)^{th} time point, and uses following algorithms to correct the weight parameter W_{d}²(k+1) and the bias parameter b_{d}²(k+1). The predictive value Δ\hat{r}₁(k+1) of the caustic concentration detection error at the (k+1)^{th} time point is obtained according to the formula (21):

$${W}_{d}^{2} ( k + 1 ) = {W}_{d}^{2} ( k ) + η \frac{\partial ( {ℒ}_{MAE}^{N} ( Δ {\hat{r}}_{1} , Δ r ) )}{\partial {W}_{d}^{2} ( k )} \qquad ( 22 )$$

$${b}_{d}^{2} ( k + 1 ) = {b}_{d}^{2} ( k ) + η \frac{\partial ( {ℒ}_{MAE}^{N} ( Δ {\hat{r}}_{1} , Δ r ) )}{\partial ( {b}_{d}^{2} ( k ) )} \qquad ( 23 )$$

In the above algorithms, η represents a learning rate of parameter correction in the online deep learning prediction model, and η=0.0005.

S4′: Establish a deep learning correction model based on a structure that is the same as a structure of the online deep learning prediction model.

Specifically, the deep learning correction model is established by using an LSTM network. An input of a single neuron, a neuron quantity, a cell node quantity, and a network layer quantity of the deep learning correction model are all the same as those of the online deep learning prediction model. All input data of the model (which is represented by the formula (3)) at the current VII time point and all previous time points k,L,2,1 is used as input data of the deep learning correction model, and all weight and bias parameters of a first layer and a second layer of the deep learning correction model are corrected by using a following objective function and training algorithm.

The objective function is as follows:

$${ℒ}_{MAE}^{k} ( Δ Δ r ) = \frac{{{\sum }_{k - N + 1}^{k} ‖ Δ r ( t ) - Δ ) ‖}_{1}}{k} \qquad ( 24 )$$

In the above objective function, k represents the current time point, and Δ [symbol] represents an output of the deep learning correction model at a t^{th} time point.

Correction algorithms for the W_{d}², b_{d}², Wₒ², and bₒ² are as follows:

$${W}_{d}^{2} ( k + 1 ) = {W}_{d}^{2} ( k ) + η \frac{\partial ( {ℒ}_{MAE}^{N} ( Δ Δ r ) )}{\partial {W}_{d}^{2} ( k )} \qquad ( 25 )$$

$${b}_{d}^{2} ( k + 1 ) = {b}_{d}^{2} ( k ) + η \frac{\partial ( {ℒ}_{MAE}^{N} ( Δ Δ r ) )}{\partial ( {b}_{d}^{2} ( k ) )} \qquad ( 26 )$$

$${W}_{o}^{2} ( k + 1 ) = {W}_{o}^{2} ( k ) + η \frac{\partial ( {ℒ}_{MAE}^{N} ( Δ Δ r ) )}{\partial {W}_{o}^{2} ( k )} \qquad ( 27 )$$

$${b}_{o}^{2} ( k + 1 ) = {b}_{o}^{2} ( k ) + η \frac{\partial ( {ℒ}_{MAE}^{N} ( Δ Δ r ) )}{\partial ( {b}_{o}^{2} ( k ) )} \qquad ( 28 )$$

In the above algorithms, η represents a learning rate of parameter correction in the correction model, and η=0.0005. The above correction algorithms can be used to correct remaining connection weight parameters W_{f}, Wᵢ, W_{C}, Wₒ, W_{d}, W_{f}², Wᵢ², W_{C}² and bias parameters b_{f}, bᵢ, b_{C}, bₒ, b_{d}, b_{f}², bᵢ², b_{C}² of the first layer and the second layer of the deep learning correction model.

S5′: Correct the online deep learning prediction model by using the deep learning correction model.

Specifically, the online deep learning prediction model is adaptively corrected by using the deep learning correction model. An upper limit of a prediction error range is set to δ,δ=1.5 g/l, and a range at an i^{th} sampling time point is set to [k, k−1,L k−99]. Within 100 consecutive sampling points at a latest time point, when a quantity of sampling points whose prediction errors |Δr(i)−Δ\hat{r}₁(i)| do not exceed the upper limit of the range in the online deep learning prediction model is less than 99, and there are 99 sampling points whose prediction errors |Δr(i)−Δ [symbol] )| do not exceed the upper limit of the range in the deep learning correction model, weight and bias parameters of each layer of the deep learning correction model are used to correct weight and bias parameters of each layer of the online deep learning prediction model to ensure that the prediction error of the online deep learning prediction model is within a specified prediction error range.

An effect of applying the prediction method for a caustic concentration detection error in the embodiments of the present disclosure to an evaporation process of an alumina plant in Shanxi is shown in Table 2.

An instrument measurement value in Table 2 is a value measured by a caustic concentration instrument online, and a compensated instrument value is a sum of the value measured by the caustic concentration instrument online and a predictive caustic concentration detection error output by the online deep learning prediction model. Table 2 takes statistics on a root mean square error (RMSE) between the instrument measurement value and the laboratory value of the caustic concentration, a qualification rate of the instrument measurement value within a specified error range of the production process, an RMSE between a compensated instrument value and the laboratory value of the caustic concentration, and a qualification rate of the compensated measurement value within a specified error range of the production process separately. It can be seen from Table 2 that after the prediction method for a caustic concentration detection error in the embodiments of the present disclosure is used to compensate for the instrument measurement value, the RMSE between the caustic concentration obtained through instrument measurement and the laboratory value of the caustic concentration can be reduced from 11.25 to 0.50, and the qualification rate can be increased from 10.75% to 99.62%, creating a condition for achieving closed-loop operation and optimization control of the evaporation process of the alumina.

TABLE 2
Effect of applying the online deep learning prediction
model for the caustic concentration

| Relevant configuration | RMSE | Qualification rate P |
|---|---|---|
| Instrument measurement value | 11.25 | 10.75% |
| Compensated instrument value | 0.50 | 99.62% |

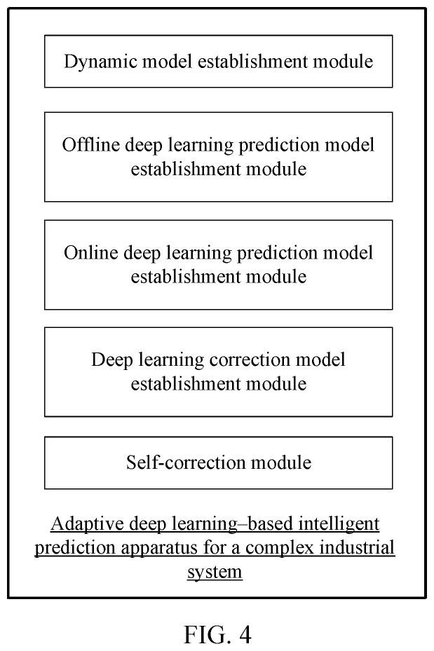

In an embodiment, as shown in FIG. 4, an adaptive deep learning-based intelligent prediction apparatus for a complex industrial system is provided, including a dynamic model establishment module, an offline deep learning prediction model establishment module, an online deep learning prediction model establishment module, a deep learning correction model establishment module, and a self-correction module.

The dynamic model establishment module is configured to establish a dynamic model for a complex industrial system.

The offline deep learning prediction model establishment module is configured to establish an offline deep learning prediction model by using the dynamic model.

The online deep learning prediction model establishment module is configured to establish an online deep learning prediction model by using the offline deep learning prediction model.

The deep learning correction model establishment module is configured to establish a deep learning correction model based on a structure that is the same as a structure of the online deep learning prediction model.

The self-correction module is configured to correct the online deep learning prediction model by using the deep learning correction model.

The online deep learning prediction model is configured to predict a parameter of the complex industrial system in real time.

In an embodiment, the dynamic model establishment module determines an input variable and an output variable of the dynamic model, where the output variable is a predicted variable. The offline deep learning prediction model establishment module establishes the offline deep learning prediction model by using an LSTM network, uses the input variable of the dynamic model as an input of the LSTM network, uses output data of the dynamic model as labels, and determines a neuron quantity, a cell node quantity, and a network layer quantity of the LSTM network, and weight and bias parameters of each layer by using an offline training algorithm based on an error between the labels and an output of the offline deep learning prediction model. The online deep learning prediction model establishment module establishes the online deep learning prediction model by using an LSTM network, where an input of a single neuron, a neuron quantity, a cell node quantity, and a network layer quantity of the online deep learning prediction model are all the same as those of the offline deep learning prediction model; uses weight and bias parameters of each layer of the offline deep learning prediction model as initial values of weight and bias parameters of the corresponding layer of the online deep learning prediction model; and corrects weight and bias parameters of a last layer of the online deep learning prediction model online by using the online training algorithm based on an error between the labels and an output of the online deep learning prediction model. The deep learning correction model establishment module establishes the deep learning correction model by using an LSTM network, where an input of a single neuron, a neuron quantity, a cell node quantity, and a network layer quantity of the deep learning correction model are all the same as those of the online deep learning prediction model; and corrects weight and bias parameters of each layer of the deep learning correction model in real time by using a training algorithm based on an error between the labels and an output of the deep learning correction model. When a preset condition is met, the self-correction module replaces weight and bias parameters of each layer of the online deep learning prediction model with weight and bias parameters of the corresponding layer of the deep learning correction model. Historical data input into the deep learning correction model is more than historical data input into the online deep learning prediction model.

In an embodiment, the correcting weight and bias parameters of a last layer of the online deep learning prediction model online is specifically correcting some weight parameters and some bias parameters of the last layer of the online deep learning prediction model online.

In an embodiment, the complex industrial system is an alumina production system, and the online deep learning prediction model is configured to predict a caustic concentration detection error of the alumina production system in real time. The caustic concentration detection error is a difference between a laboratory value of a caustic concentration and a caustic concentration measured by an online caustic concentration detection instrument.

For specific limitations on the intelligent prediction apparatus for a complex industrial system, reference may be made to the above limitations on the intelligent prediction method for a complex industrial system. Details are not described herein again. The modules of the intelligent prediction apparatus for a complex industrial system may be implemented in whole or in part by software, hardware, or any combination thereof. The modules may be embedded in or independent of a processor of a computer device in a form of hardware, or stored in a memory of the computer device in a form of software, such that the processor can easily invoke and execute corresponding operations of the modules.

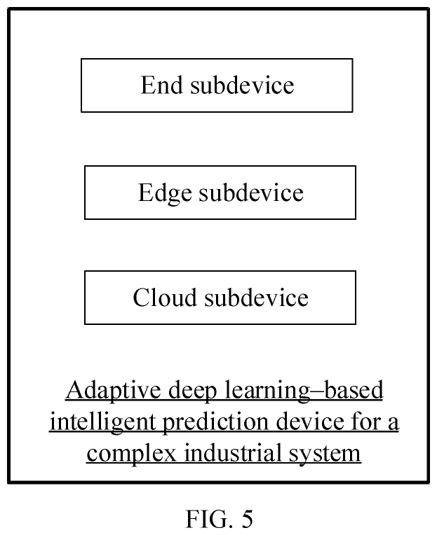

In an embodiment, as shown in FIG. 5, an adaptive deep learning-based intelligent prediction device for a complex industrial system to implement the intelligent prediction method in the above embodiments is provided, including: an end subdevice, an edge subdevice, and a cloud subdevice. The end subdevice is configured to collect input data and output data of the complex industrial system. The edge subdevice is configured to predict a parameter of the complex industrial system in real time by using an online deep learning prediction model. The cloud subdevice is configured to train a deep learning correction model and correct the online deep learning prediction model by using the deep learning correction model.

In an embodiment, a computer-readable storage medium is provided. The computer-readable storage medium stores a computer program, and the computer program is executed by a processor to implement the intelligent prediction method for a complex industrial system in the above embodiments.

Those skilled in the art may combine different embodiments described in this specification and characteristics of the different embodiments without mutual contradiction.

To sum up, according to the intelligent prediction method, apparatus, and device for a complex industrial system in the embodiments of the present disclosure, in order to resolve problems of low prediction accuracy and poor real-time prediction performance of the complex industrial system, the offline deep learning prediction model, the online deep learning prediction model, the deep learning correction model, and a self-correction mechanism have been established to achieve accurate real-time prediction of the complex industrial system.

The above are merely specific implementations of the present disclosure, and the protection scope of the present disclosure is not limited thereto. Any modification or replacement easily conceived by those skilled in the art within the technical scope of the present disclosure should fall within the protection scope of the present disclosure. Therefore, the protection scope of the present disclosure shall be subject to the protection scope of the claims.

1. An adaptive deep learning-based intelligent prediction method for a complex industrial system, wherein the method comprises:
establishing a dynamic model for a complex industrial system;
establishing an offline deep learning prediction model by using the dynamic model;
establishing an online deep learning prediction model by using the offline deep learning prediction model;
establishing a deep learning correction model based on a structure that is the same as a structure of the online deep learning prediction model; and
correcting the online deep learning prediction model by using the deep learning correction model; wherein
the online deep learning prediction model is configured to predict a parameter of the complex industrial system in real time.

2. The method according to claim 1, wherein the establishing a dynamic model for a complex industrial system comprises: determining an input variable and an output variable of the dynamic model, wherein the output variable is a predicted variable;
the establishing an offline deep learning prediction model by using the dynamic model comprises: establishing the offline deep learning prediction model by using a long-short term memory (LSTM) network, using the input variable of the dynamic model as an input of the LSTM network, using output data of the dynamic model as labels, and determining a neuron quantity, a cell node quantity, and a network layer quantity of the LSTM network, and weight and bias parameters of each layer by using an offline training algorithm based on an error between the labels and an output of the offline deep learning prediction model;
the establishing an online deep learning prediction model by using the offline deep learning prediction model comprises: establishing the online deep learning prediction model by using an LSTM network, wherein an input of a single neuron, a neuron quantity, a cell node quantity, and a network layer quantity of the online deep learning prediction model are all the same as those of the offline deep learning prediction model; using weight and bias parameters of each layer of the offline deep learning prediction model as initial values of weight and bias parameters of the corresponding layer of the online deep learning prediction model; and correcting weight and bias parameters of a last layer of the online deep learning prediction model online by using the online training algorithm based on an error between the labels and an output of the online deep learning prediction model;
the establishing a deep learning correction model based on a structure that is the same as a structure of the online deep learning prediction model comprises: establishing the deep learning correction model by using an LSTM network, wherein an input of a single neuron, a neuron quantity, a cell node quantity, and a network layer quantity of the deep learning correction model are all the same as those of the online deep learning prediction model; and correcting weight and bias parameters of each layer of the deep learning correction model in real time by using a training algorithm based on an error between the labels and an output of the deep learning correction model; and
the correcting the online deep learning prediction model by using the deep learning correction model comprises: when a preset condition is met, replacing weight and bias parameters of each layer of the online deep learning prediction model with weight and bias parameters of the corresponding layer of the deep learning correction model; wherein
historical data input into the deep learning correction model is more than historical data input into the online deep learning prediction model.

3. The method according to claim 2, wherein the correcting weight and bias parameters of a last layer of the online deep learning prediction model online is specifically correcting some weight parameters and some bias parameters of the last layer of the online deep learning prediction model online.

4. The method according to claim 1, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

5. The method according to claim 2, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

6. The method according to claim 3, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

7. An adaptive deep learning-based intelligent prediction apparatus for a complex industrial system, wherein the apparatus comprises:
a dynamic model establishment module configured to establish a dynamic model for a complex industrial system;
an offline deep learning prediction model establishment module configured to establish an offline deep learning prediction model by using the dynamic model;
an online deep learning prediction model establishment module configured to establish an online deep learning prediction model by using the offline deep learning prediction model;
a deep learning correction model establishment module configured to establish a deep learning correction model based on a structure that is the same as a structure of the online deep learning prediction model; and
a self-correction module configured to correct the online deep learning prediction model by using the deep learning correction model; wherein
the online deep learning prediction model is configured to predict a parameter of the complex industrial system in real time.

8. The apparatus according to claim 7, wherein the dynamic model establishment module determines an input variable and an output variable of the dynamic model, wherein the output variable is a predicted variable;
the offline deep learning prediction model establishment module establishes the offline deep learning prediction model by using an LSTM network, uses the input variable of the dynamic model as an input of the LSTM network, uses output data of the dynamic model as labels, and determines a neuron quantity, a cell node quantity, and a network layer quantity of the LSTM network, and weight and bias parameters of each layer by using an offline training algorithm based on an error between the labels and an output of the offline deep learning prediction model;
the online deep learning prediction model establishment module establishes the online deep learning prediction model by using an LSTM network, wherein an input of a single neuron, a neuron quantity, a cell node quantity, and a network layer quantity of the online deep learning prediction model are all the same as those of the offline deep learning prediction model; uses weight and bias parameters of each layer of the offline deep learning prediction model as initial values of weight and bias parameters of the corresponding layer of the online deep learning prediction model; and corrects weight and bias parameters of a last layer of the online deep learning prediction model online by using the online training algorithm based on an error between the labels and an output of the online deep learning prediction model;
the deep learning correction model establishment module establishes the deep learning correction model by using an LSTM network, wherein an input of a single neuron, a neuron quantity, a cell node quantity, and a network layer quantity of the deep learning correction model are all the same as those of the online deep learning prediction model; and corrects weight and bias parameters of each layer of the deep learning correction model in real time by using a training algorithm based on an error between the labels and an output of the deep learning correction model; and
when a preset condition is met, the self-correction module replaces weight and bias parameters of each layer of the online deep learning prediction model with weight and bias parameters of the corresponding layer of the deep learning correction model; wherein
historical data input into the deep learning correction model is more than historical data input into the online deep learning prediction model.

9. The apparatus according to claim 8, wherein the correcting weight and bias parameters of a last layer of the online deep learning prediction model online is specifically correcting some weight parameters and some bias parameters of the last layer of the online deep learning prediction model online.

10. The apparatus according to claim 7, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

11. The apparatus according to claim 8, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

12. The apparatus according to claim 9, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

13. An adaptive deep learning-based intelligent prediction device for a complex industrial system to implement the method according to claim 1, wherein the device comprises an end subdevice, an edge subdevice, and a cloud subdevice;
the end subdevice is configured to collect input data and output data of the complex industrial system;
the edge subdevice is configured to predict a parameter of the complex industrial system in real time by using an online deep learning prediction model; and
the cloud subdevice is configured to train a deep learning correction model and correct the online deep learning prediction model by using the deep learning correction model.

14. The device according to claim 13, wherein a dynamic model is established for the complex industrial system, which comprises: determining an input variable and an output variable of the dynamic model, wherein the output variable is a predicted variable;
an offline deep learning prediction model is established by using the dynamic model, which comprises: establishing the offline deep learning prediction model by using an LSTM network, using the input variable of the dynamic model as an input of the LSTM network, using output data of the dynamic model as labels, and determining a neuron quantity, a cell node quantity, and a network layer quantity of the LSTM network, and weight and bias parameters of each layer by using an offline training algorithm based on an error between the labels and an output of the offline deep learning prediction model;
the online deep learning prediction model is established by using the offline deep learning prediction model, which comprises: establishing the online deep learning prediction model by using an LSTM network, wherein an input of a single neuron, a neuron quantity, a cell node quantity, and a network layer quantity of the online deep learning prediction model are all the same as those of the offline deep learning prediction model; using weight and bias parameters of each layer of the offline deep learning prediction model as initial values of weight and bias parameters of the corresponding layer of the online deep learning prediction model; and correcting weight and bias parameters of a last layer of the online deep learning prediction model online by using the online training algorithm based on an error between the labels and an output of the online deep learning prediction model;
the deep learning correction model is established based on a structure that is the same as a structure of the online deep learning prediction model, which comprises: establishing the deep learning correction model by using an LSTM network, wherein an input of a single neuron, a neuron quantity, a cell node quantity, and a network layer quantity of the deep learning correction model are all the same as those of the online deep learning prediction model; and correcting weight and bias parameters of each layer of the deep learning correction model in real time by using a training algorithm based on an error between the labels and an output of the deep learning correction model; and
the online deep learning prediction model is corrected by using the deep learning correction model, which comprises: when a preset condition is met, replacing weight and bias parameters of each layer of the online deep learning prediction model with weight and bias parameters of the corresponding layer of the deep learning correction model; wherein
historical data input into the deep learning correction model is more than historical data input into the online deep learning prediction model.

15. The device according to claim 14, wherein the correcting weight and bias parameters of a last layer of the online deep learning prediction model online is specifically correcting some weight parameters and some bias parameters of the last layer of the online deep learning prediction model online.

16. The device according to claim 13, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

17. The device according to claim 14, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

18. The device according to claim 15, wherein the complex industrial system is an alumina production system, and the online deep learning prediction model is configured to predict a caustic concentration detection error of the alumina production system in real time; and the caustic concentration detection error is a difference between a laboratory value of a caustic concentration and a caustic concentration measured by an online caustic concentration detection instrument.

19. A computer-readable storage medium storing a computer program, wherein the computer program is executed by a processor to implement the method according to claim 1.
